(19) United States
(12) Patent Application Publication
(10) Pub. No.: US 2019/0181291 A1
(43) Pub. Date: Jun. 13, 2019

(54) SOLAR CELL AND METHOD FOR MANUFACTURING SAME

(71) Applicant: Panasonic Intellectual Property Management Co., Ltd., Osaka (JP)

(72) Inventors: Tsuyoshi Takahama, Osaka (JP); Wataru Shinohara, Fukushima (JP); Yoshinari Ichihashi, Osaka (JP); Naoki Yoshimura, Osaka (JP)

(73) Assignee: Panasonic Intellectual Property Management Co., Ltd., Osaka (JP)

(21) Appl. No.: 16/279,359

(22) Filed: Feb. 19, 2019

Related U.S. Application Data
(63) Continuation of application No. PCT/JP2017/025568, filed on Jul. 13, 2017.

(30) Foreign Application Priority Data
Aug. 25, 2016 (JP) 2016-164965

(51) Int. Cl. H01L 31/0747; H01L 31/0216; H01L 31/0224; H01L 31/18; H01L 31/20; H01L 21/268

(52) U.S. Cl. CPC H01L 31/0747; H01L 31/02167; H01L 31/022425; H01L 21/268; H01L 31/1864; H01L 31/202; H01L 31/1868

(57) ABSTRACT

A method for manufacturing a solar cell, including: a step for irradiating a semiconductor substrate to cause the surface to become amorphous and to form an intrinsic amorphous layer, a first conductivity-type layer, and a second conductivity-type layer; and a step for introducing hydrogen into the intrinsic amorphous layer, the first conductivity-type layer, and the second conductivity-type layer.

### INCORPORATION BY REFERENCE

This application is a U.S. continuation application of PCT International Patent Application Number PCT/JP2017/025568, filed Jul. 13, 2017, claiming the benefit of priority of Japanese Patent Application Number 2016-164965, filed Aug. 25, 2016, the entire contents of which are hereby incorporated by reference.

### TECHNICAL FIELD

The present disclosure relates to a solar cell and a method for manufacturing the solar cell.

### BACKGROUND ART

As a solar cell having a high power generation efficiency, there is known a solar cell in which crystalline silicon is laminated with an amorphous silicon layer. For a solar cell like this, a method is adopted in which an amorphous silicon layer is formed on a cleaned surface of crystalline silicon through a chemical vapor deposition (CVD) method employing a silicon containing gas such as silane gas.

On the other hand, there is disclosed a technique for making a surface of crystalline silicon amorphous by irradiating a laser beam on the surface of the crystalline silicon.

### SUMMARY

### Technical Problem

Incidentally, a vacuum device needs to be used in the amorphous silicon layer forming method employing CVD. When forming an amorphous silicon layer on crystalline silicon employing CVD, impurities remain on an interface between the crystalline silicon and the amorphous silicon layer. These impurities affect the crystalline properties of amorphous silicon formed on the surface of the crystalline silicon, on which the impurities remain, or the electric properties of a completed solar cell. Due to this, less or no such impurities preferably remain on the interface. However, it is difficult to prevent the adherence of impurities to a crystalline silicon substrate in a process of carrying the crystalline silicon substrate into the vacuum device.

The present disclosure has been made in view of these situations, and it is an advantage of the present disclosure to provide a method for manufacturing a solar cell and a solar cell that can reduce impurities on an interface between crystalline silicon and an amorphous silicon layer.

### Solution To Problem

A method for manufacturing a solar cell of the present disclosure includes a first step of forming an amorphous silicon layer by irradiating a crystalline silicon substrate with a laser beam to make a surface of the crystalline silicon substrate amorphous, and a second step of introducing hydrogen into the amorphous silicon layer.

A solar cell of the present disclosure is a solar cell including an amorphous silicon layer on a surface of a crystalline silicon substrate, and an oxygen concentration on an interface between the crystalline silicon substrate and the amorphous silicon layer is the same as an oxygen concentration in a bulk of the crystalline silicon substrate.

### Advantageous Effect of the Disclosure

According to the present disclosure, the solar cell can be provided by forming the amorphous silicon layer without employing CVD.

### BRIEF DESCRIPTION OF DRAWINGS

The figures depict one or more implementations in accordance with the present teaching, by way of example only, not by way of limitations. In the figures, like reference numerals refer to the same or similar elements.

FIG. 1 is a drawing illustrating the configuration of a solar cell according to an embodiment of the present disclosure.

FIG. 2 is a drawing illustrating the configuration of the solar cell according to the embodiment of the present disclosure.

FIG. 3 is a drawing illustrating a method for manufacturing a solar cell according to the embodiment of the present disclosure.

FIG. 4 is a drawing illustrating the method for manufacturing a solar cell according to the embodiment of the present disclosure.

FIG. 5 is a drawing illustrating the method for manufacturing a solar cell according to the embodiment of the present disclosure.

FIG. 6 is a drawing illustrating the method for manufacturing a solar cell according to the embodiment of the present disclosure.

FIG. 7 is a drawing illustrating a method for manufacturing a solar cell according to Modified Example 1 of the present disclosure.

FIG. 8 is a drawing illustrating the method for manufacturing a solar cell according to Modified Example 1 of the present disclosure.

FIG. 9 is a drawing illustrating the method for manufacturing a solar cell according to Modified Example 1 of the present disclosure.

FIG. 10 is a drawing illustrating the method for manufacturing a solar cell according to Modified Example 1 of the present disclosure.

FIG. 11 is a drawing illustrating a method for manufacturing a solar cell according to Modified Example 2 of the present disclosure.

FIG. 12 is a drawing illustrating the configuration of a solar cell according to a different embodiment of the present disclosure.

FIG. 13 is a drawing illustrating a method for manufacturing a solar cell according to the different embodiment of the present disclosure.

FIG. 14 is a drawing illustrating the method for manufacturing a solar cell according to the different embodiment of the present disclosure.

FIG. 15 is a drawing illustrating the method for manufacturing a solar cell according to the different embodiment of the present disclosure.

FIG. 16 is a drawing illustrating the method for manufacturing a solar cell according to the different embodiment of the present disclosure.

### DESCRIPTION OF EMBODIMENTS

Hereinafter, referring to drawings, embodiments of the present disclosure will be described in detail. In the description of the drawings, like reference numerals are given to like elements, and that repeated descriptions are omitted as appropriate.

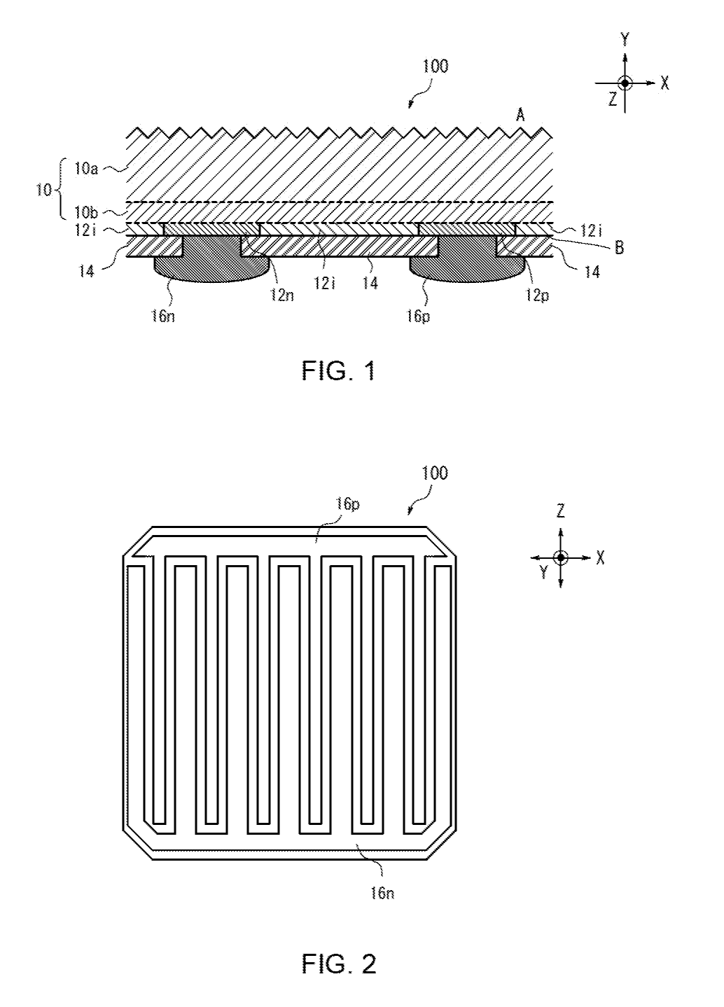

FIG. 1 is a sectional view illustrating the structure of a solar cell 100 according to an embodiment. The solar cell 100 includes a semiconductor substrate 10, an intrinsic amorphous layer 12i, a first conductivity-type layer 12n, a second conductivity-type layer 12p, an insulation layer 14 and an electrode layer 16. The electrode layer 16 constitutes an n-side electrode 16n or a p-side electrode 16p. The solar cell 100 is a rear surface junction solar cell in which the n-side electrode 16n and the p-side electrode 16p are provided on a rear surface side, and no electrode layer 16 is provided on a light receiving surface side.

The semiconductor substrate 10 has a first main surface A provided on the light receiving surface side and a second main surface B provided on the rear surface side. The semiconductor substrate 10 absorbs mainly light incident on the first main surface A and generates electrons and positive holes as carriers. The semiconductor substrate 10 is made up of a crystalline silicon substrate such as a crystalline silicon wafer having a conductivity type that is n type or p type. The semiconductor substrate 10 includes a bulk portion 10a having a low doping concentration and a surface portion 10b having a high doping concentration, the bulk portion 10a and the surface portion 10b having a conductivity type that is n type or p type, and an amorphous silicon layer, which will be described later. The bulk portion 10a and the surface portion 10b make up a crystalline semiconductor layer. A texture structure for scattering incident light may be given to the first main surface A of the semiconductor substrate 10. On the other hand, no texture structure is preferably formed on the second main surface B of the semiconductor substrate 10 because the first conductivity-type layer 12n and the second conductivity-type layer 12p, which will both be described later, are provided on the second main surface B in such a way as to be interlaid with each other. The semiconductor substrate 10 of this embodiment includes the bulk portion 10a of an n-type single crystal silicon and the surface portion 10b of an n⁺ type, and the amorphous silicon layer, which will be described later.

Here, the light receiving surface means a main surface of the solar cell 100 on which light (solar light) is incident, and specifically means a surface on which most of the light incident on the solar cell 100 is incident. On the other hand, the rear surface means the other main surface that is opposite to the light receiving surface. Specifically, the light receiving surface side of the solar cell 100 is disposed so as to face a light transmitting base material (not shown) such as a glass substrate when a solar cell module is formed.

The amorphous silicon layer (the intrinsic amorphous layer 12i, the first conductivity-type layer 12n, the second conductivity-layer 12p) is provided on the second main surface B of the semiconductor substrate 10. In this embodiment, the first conductivity-type layer 12n and the second conductivity-type layer 12p are an n type conductivity and a p type conductivity, respectively and are formed so as to correspond to the n-side electrode 16n and the p-side electrode 16p, respectively. As illustrated in FIG. 2, the n-side electrode 16n and the p-side electrode 16p are formed in comb-like shapes with the teeth of the combs being inserted in between each other. The first conductivity-type layer 12n and the second conductivity-type layer 12p are arranged alternately in an X direction. In this embodiment, the second main surface is covered substantially entirely by the first conductivity-type layer 12n and the second conductivity-type layer 12p.

In this embodiment, the first conductivity-type layer 12n and the second conductivity-type layer 12p may contain microcrystal silicon. The microcrystal silicon refers to a semiconductor in which crystal silicon is precipitated in amorphous silicon.

The intrinsic amorphous layer 12i is made up of an i-type amorphous silicon containing hydrogen (H). The first conductivity-type layer 12n is made up, for example, of an n-type amorphous silicon to which a dopant such as phosphorus (P), arsenic (As) or the like is added and which contains hydrogen (H). The second conductivity-type layer 12p is made up, for example, of a p-type amorphous silicon to which a dopant such as boron (B) or the like is added and which contains hydrogen (H). The intrinsic amorphous layer 12i, the first conductivity-type layer 12n and the second conductivity-type layer 12p each have a thickness, for example, in the order of several nm to 100 nm. The i-type amorphous silicon is an amorphous silicon film containing dopants substantially equal to the dopant concentration of the semiconductor substrate 10 and has a dopant concentration of 1×10¹⁷ cm⁻³ or smaller. On the other hand, the n-type amorphous silicon and the p-type amorphous silicon have a dopant concentration of 5×10²¹ cm⁻³ or smaller, as a typical example.

The insulation layer 14 is formed on the intrinsic amorphous layer 12i, the first conductivity-type layer 12n and the second conductivity-type layer 12p. The insulation layer 14 is provided so as to straddle the first conductivity-type layer 12n and the second conductivity-type layer 12p from the intrinsic amorphous layer 12i and is not provided at central portions of the first conductivity-type layer 12n and the second conductivity-type layer 12p in the X direction. The n-side electrode 16n and the p-side electrode 16p are provided on areas where the insulation layer 14 is not provided.

The insulation layer 14 is formed, for example, of silicon oxide (SiO₂), silicon nitride (SiN), silicon oxynitride (SiON) or the like. The insulation layer 14 is desirably formed of silicon nitride and preferably contains hydrogen.

The n-side electrode 16n, which collects electrons, is formed on the first conductivity-type layer 12n. The p-side electrode 16p, which collects positive holes, is formed on the second conductivity-type layer 12p. The insulation layer 14 is disposed between the n-side electrode 16n and the p-side electrode 16p, and the n-side electrode 16n and the p-side electrode 16p are electrically insulated by the insulation layer 14 in the X direction.

The n-side electrode 16n and the p-side electrode 16p can be made up of a metallic layer or a transparent conductive layer. For example, a transparent conductive oxide (TCO) such as tin oxide (SnO₂), zinc oxide (ZnO), indium tin oxide (ITO) or the like is preferably provided on areas of the n-side electrode 16n and the p-side electrode that are brought into contact with the first conductivity-type layer 12n or the second conductivity-type layer 12p. In addition, for example, the n-side electrode 16n and the p-side electrode 16p preferably contain metal such as copper (Cu), tin (Sn), gold (Au), silver (Ag), aluminum (Al) or the like on the transparent conductive oxide. The n-side electrode 16n and the p-side electrode 16p are preferably made up of a laminated body of conductive layers. In this embodiment, this is a laminated structure of an aluminum (Al) layer, a barrier metal layer and a copper (Cu) layer.

A method for forming the n-side electrode 16n and the p-side electrode 16p is not particularly limited, and the n-side electrode 16n and the p-side electrode 16p can be formed by a film forming method such as a sputtering method, a chemical vapor deposition (CVD) method, and the like, a plating method, a combination thereof, and the like.

A passivation layer may be provided on the first main surface A of the semiconductor substrate 10. The passivation layer is formed, for example, of an i-type amorphous silicon containing hydrogen and should be given a thickness in the order of several nm to 25 nm. Additionally, a diffusion layer having an n type or p type conductivity may be provided on the first main surface A of the semiconductor substrate 10.

An insulation layer having a function of a reflection prevention film and a protection film may be provided on the first main surface A of the semiconductor substrate 10. An insulation layer functioning as a reflection prevention film may be formed, for example, of silicon oxide, silicon nitride, silicon oxynitride, or the like. A film thickness is in the order of 80 nm to 1000 nm.

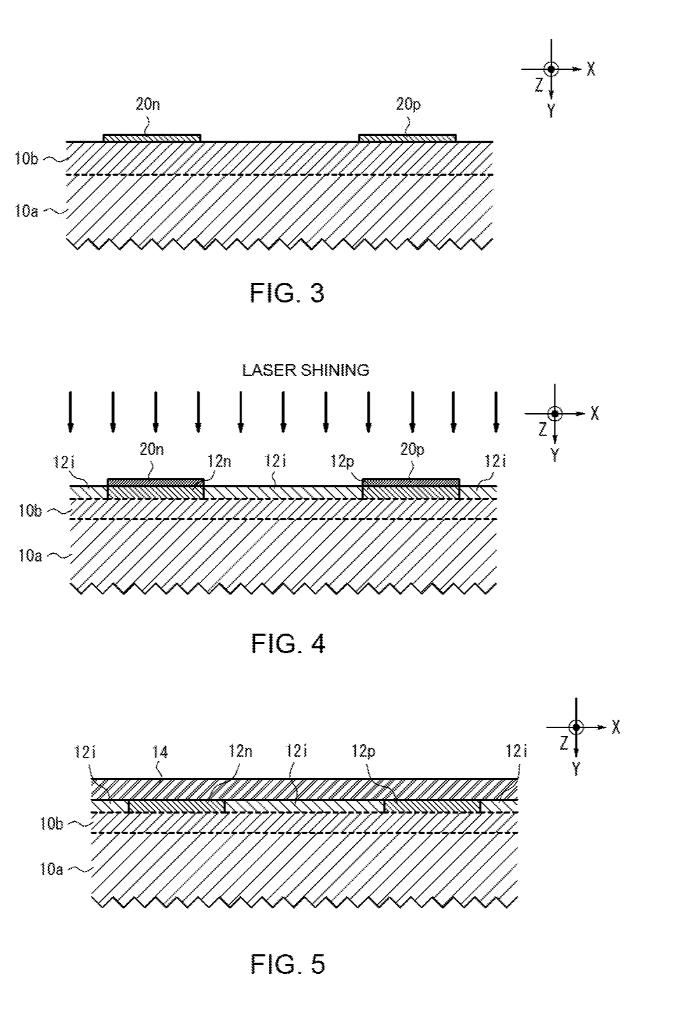

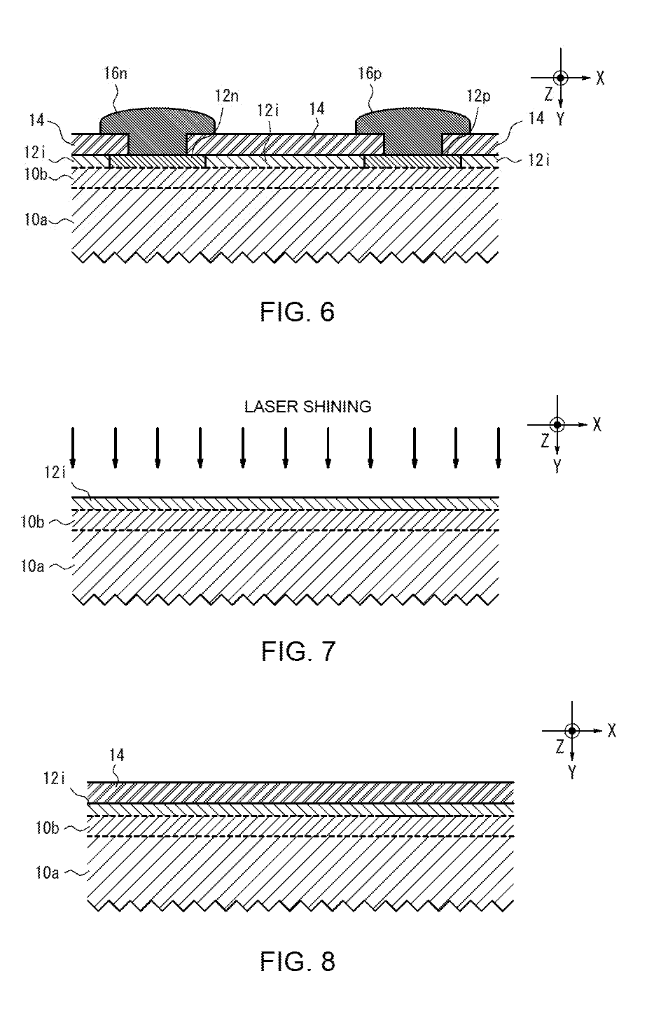

Following this, referring to FIGS. 3 to 6, a method for manufacturing the solar cell 100 will be described.

Firstly, a texture structure is formed on the first main surface A of the semiconductor substrate 10. The texture structure is formed by submerging a silicon single crystal substrate of a crystal orientation (100) in an alkaline aqueous solution of sodium hydroxide (NaOH) or the like to expose a crystal orientation (111) surface through anisotropic etching.

Next, as illustrated in FIG. 3, an n-type dopant diffusion layer 20n and a p-type dopant diffusion layer 20p are formed on the second main surface B of the semiconductor substrate 10 on which no texture structure is formed. The n-type dopant diffusion layer 20n is a resin layer containing a dopant such as phosphorus (P), arsenic (As), or the like that is an n-type dopant. The n-type dopant diffusion layer 20n is formed on an area of the second main surface B of the semiconductor substrate 10 that constitutes the first conductivity-type layer 12n. The p-type dopant diffusion layer 20p is a resin layer containing a dopant such as boron (B) or the like that is a p-type dopant. The p-type dopant diffusion layer 20p is formed on an area of the second main surface B of the semiconductor substrate 10 that constitutes the second conductivity-type layer 12p. The n-type dopant diffusion layer 20n and the p-type dopant diffusion layer 20p do not always have to have the resin configuration like the resin layer that contains the dopant, and may be configured as a dopant containing inorganic layer like a glass coating.

Next, as illustrated in FIG. 4, a laser is irradiated on the n-type dopant diffusion layer 20n, the p-type dopant diffusion layer 20p and the semiconductor substrate 10 to form the intrinsic amorphous layer 12i, the first conductivity-type layer 12n and the second conductivity-type layer 12p. In this embodiment, the crystalline semiconductor on the surface of the semiconductor substrate 10 is modified into an amorphous semiconductor by irradiating a laser on the surface of the second main surface B of the semiconductor substrate 10. Consequently, a crystallization rate of the surface of the second main surface B of the semiconductor substrate 10 after laser irradiation becomes lower than a crystallization rate of (the bulk portion 10a of) the semiconductor substrate 10. A laser to be irradiated is preferably a femtosecond pulse laser. The wavelength of a laser is preferably in a range of 250 nm or greater to 1600 nm or smaller. For example, when the wavelength of a laser to be irradiated is 267 nm, a laser of an energy density of 36 mJ/cm² or smaller should be irradiated, when the wavelength of a laser to be irradiated is 400 nm, a laser of an energy density of 60 mJ/cm² or smaller should be irradiated, when the wavelength of a laser to be irradiated is 800 nm, a laser of an energy density of 1800 mJ/cm² or smaller should be irradiated, and when the wavelength of a laser to be irradiated is 1550 nm, a laser of an energy density of 190 mJ/cm² or smaller should be irradiated.

By treating in this way, an area that is at a depth of several nm or greater to 100 nm or smaller from the surface of the second main surface B of the semiconductor substrate 10 is made amorphous. At the same time, the n-type dopant and the p-type dopant are diffused from the n-type dopant diffusion layer 20n and the p-type dopant diffusion layer 20p, respectively, and the first conductivity-type layer 12n and the second conductivity-type layer 12p are formed below the areas where the n-type dopant diffusion layer 20n and the p-type dopant diffusion layer 20 are formed. Then, the area where the n-type dopant diffusion layer 20n and the p-type dopant diffusion layer 20p are not formed constitutes the intrinsic amorphous layer 12i.

As this occurs, since an interface between the semiconductor substrate 10, and the intrinsic amorphous layer 12i, the first conductivity-type layer 12n and the second conductivity-type layer 12p, is not exposed externally, the oxygen concentration of the semiconductor substrate 10 and the oxygen concentration in the intrinsic amorphous layer 12i, the first conductivity-type layer 12n and the second conductivity-type layer 12p become substantially the same. The oxygen concentration can be measured by secondary ion mass spectroscopy (SIMS). Here, the oxygen concentrations being substantially the same means that a difference in oxygen concentration between oxygen concentrations measured by SIMS is no more than a 10-fold difference.

Next, as illustrated in FIG. 5, the insulation layer 14 is formed on the intrinsic amorphous layer 12i, the first conductivity-type layer 12n and the second conductivity-type layer 12p. A method for forming the insulation layer 14 is not particularly limited, and hence, the insulation layer 14 can be formed through a chemical vapor deposition (CVD) method such as a plasma CVD method employing a mixed gas of a hydrogenated silicon gas such as a silane gas and oxygen or nitrogen. By doing this, silicon oxide (SiO₂), silicon nitride (SiN), and silicon oxynitride (SiON), which all contain hydrogen, can be formed. Surfaces of the intrinsic amorphous layer 12i, the first conductivity-type layer 12n and the second conductivity-type layer 12p are preferably cleaned before forming the insulation layer 14.

An annealing treatment is preferably performed after or during the formation of the insulation layer 14. Hydrogen is introduced from the insulation layer 14 into the intrinsic amorphous layer 12i, the first conductivity-type layer 12n and the second conductivity-type layer 12p by heat generated from the annealing treatment, whereby defects within the intrinsic amorphous layer 12i, the first conductivity-type layer 12n and the second conductivity-type layer 12p are inactivated (passivation).

Thereafter, as illustrated in FIG. 6, the insulation layer 14 formed on the first conductivity-type layer 12n and the second conductivity-type layer 12p is partially removed. Then, the n-side electrode 16n and the p-side electrode 16p are formed on the first conductivity-type layer 12n and the second conductivity-type layer 12p that are exposed from the insulation layer 14. The insulation layer 14 can be removed by applying a conventional lithography technique, laser machining technique, or the like. Then, the n-side electrode 16n and the p-side electrode 16p can be formed by applying a conventional thin film forming method, a plating method, or the like.

The surfaces of the first conductivity-type layer 12n and the second conductivity-type layer 12p that are exposed from the partially removed insulation layer 14 may be re-crystallized before the n-side electrode 16n and the p-side electrode 16p are formed. A laser annealing technique should be applied to the re-crystallization. By doing this, an interface resistance between the first conductivity-type layer 12n and the n-side electrode 6n and an interface resistance between the second conductivity-type layer 12p and the p-side electrode 16p can be reduced.

The solar cell 100 of this embodiment can be formed by the manufacturing method described heretofore. By forming the solar cell 100 using the manufacturing method, a good junction interface between the crystalline semiconductor and the amorphous silicon layer of the semiconductor substrate 10 can be formed. In the solar cell employing the crystalline silicon substrate, the passivation layer is provided on the surface thereof to reduce the defect level of the surface of the substrate. Conventionally, silicon oxide, silicon nitride, and amorphous silicon that are formed by a vacuum film forming method such as the chemical vapor deposition method are used as the passivation layer. However, when forming the passivation layer using the chemical vapor deposition method, impurities are occasionally mixed into between the crystalline semiconductor and the passivation layer. According to the method for manufacturing a solar cell of this embodiment, since the interface between the crystalline semiconductor and the amorphous silicon layer is not exposed externally, impurities can be restricted from being mixed into the interface. This can reduce the defect level of the interface between the crystalline semiconductor and the amorphous silicon layer, whereby carriers can be collected with good efficiency.

In this embodiment, hydrogen is introduced to the surface of the semiconductor substrate 10 that is made amorphous, such as the intrinsic amorphous layer 12i, the first conductivity-type layer 12n and the second conductivity-type layer 12p, by performing the annealing treatment after the insulation layer 14 is formed. However, the method for introducing hydrogen to the surface of the semiconductor substrate 10 that is made amorphous is not limited to the method described above. For example, there are adopted methods such as a method in which the surface of the semiconductor substrate 10 is exposed to an atmospheric pressure plasma of hydrogen, a method in which a hydrogen plasma treatment is applied to the surface of the semiconductor substrate 10 in a vacuum environment, and a method in which an ion injection treatment and a hydrogen plasma treatment are applied to the surface of the semiconductor substrate 10.

In this embodiment, the semiconductor substrate 10 is described as including the bulk portion 10a of the n-type single crystal silicon and the n⁺-type surface portion 10b. However, the semiconductor substrate 10 may include only the bulk portion 10a without providing the surface portion 10b. This will be true with a surface portion 110b of another embodiment of the present disclosure, which will be described later.

### Modified Example 1

Hereinafter, referring to FIGS. 7 to 10, Modified Example 1 will be described, which is a modification to the manufacturing method for manufacturing the solar cell 100 of the embodiment.

Firstly, a texture structure is formed on the first surface A of the semiconductor substrate 10. Next, as illustrated in FIG. 7, an intrinsic amorphous layer 12i is formed on the second main surface B of the semiconductor substrate 10. In this modified example, the surface of the second main surface B of the semiconductor substrate 10 is made amorphous by irradiating a laser on the relevant surface. A laser to be irradiated may be similar to the laser used in the embodiment described above.

Next, as illustrated in FIG. 8, an insulation layer 14 is formed on the intrinsic amorphous layer 12i. A method for forming the insulation layer 14 includes a chemical vapor deposition (CVD) method such as a plasma CVD method employing a mixed gas of a hydrogenated silicon gas such as a silane gas and oxygen or nitrogen, and hence, the insulation layer 14 should be formed using the chemical vapor deposition (CVD) method.

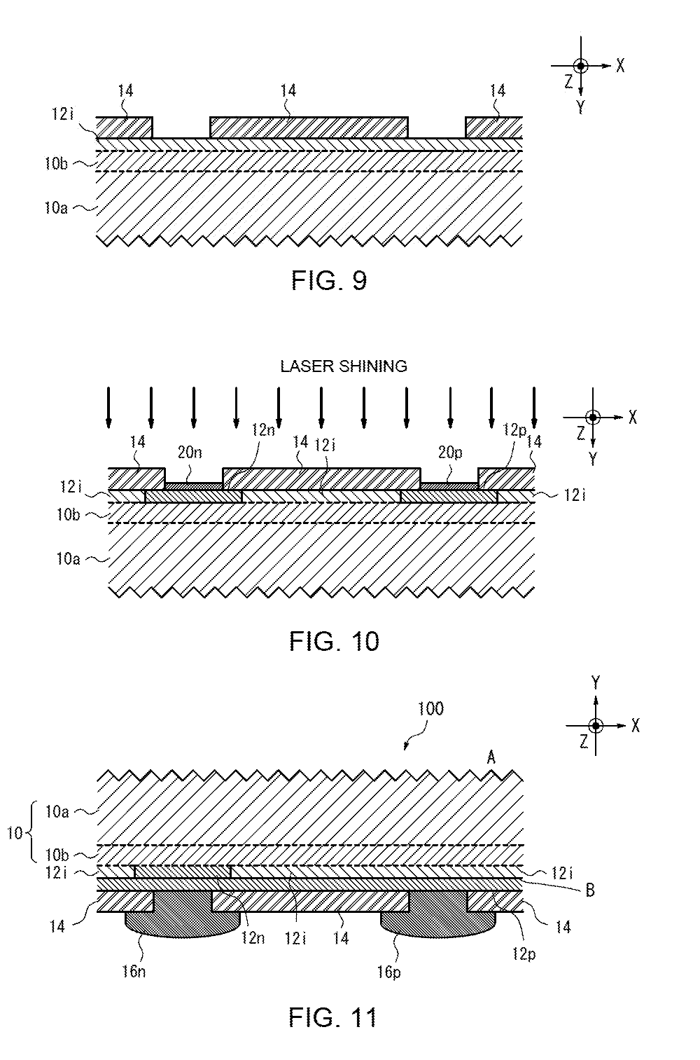

Next, as illustrated in FIG. 9, the insulation layer 14 formed on the first conductivity-type layer 12n and the second conductivity-layer 12p is partially removed. The insulation layer 14 can be removed by applying a conventional lithography technique, laser machining technique, or the like. An annealing treatment is preferably performed after or during formation of the insulation layer 14. This enables hydrogen to be introduced from the insulation layer 14 into the intrinsic amorphous layer 12i, whereby defects in the intrinsic amorphous layer 12i is inactivated (passivation).

Next, as illustrated in FIG. 10, impurities are added to part of the intrinsic amorphous layer 12i by making use of openings formed by removing the insulation layer 14. An n-type dopant diffusion layer 20n and a p-type dopant diffusion layer 20p are formed on a surface of the intrinsic amorphous layer 12i where the insulation layer 14 is removed. Thereafter, a laser is irradiated on the n-type dopant diffusion layer 20n and the p-type dopant diffusion layer 20p. This enables an n-type dopant and a p-type dopant to be diffused from the n-type dopant diffusion layer 20n and the p-type dopant diffusion layer 20p, respectively, whereby a first conductivity-type layer 12n and a second conductivity-type layer 12p are formed.

Surfaces of the first conductivity-type layer 12n and the second conductivity-type layer 12p may be re-crystallized at the same time as the first conductivity-type layer 12n and the second conductivity-type layer 12p are formed.

Thereafter, an n-side electrode 16n and a p-side electrode 16p are formed. The n-side electrode 16n and the p-side electrode 16p can be formed by applying the sputtering technique or the like as done in the embodiment described above. This can form a solar cell 100 having a like structure to that illustrated in FIG. 1.

### Modified Example 2

In the solar cell 100 of the embodiment described above, the second conductivity-type layer 12p to which the p-type dopant is added is described as being formed by irradiating the laser. However, the configuration is not limited thereto. As illustrated in FIG. 11, a solar cell 102 may be provided in which the second conductivity-type layer 12p is not provided, but a second conductivity-type layer 22p is provided that is formed by a method employing CVD or the like.

In this case, only an n-type dopant diffusion layer 20n is formed on the second main surface B of the semiconductor substrate 10, and a first conductivity-type layer 12n and an intrinsic amorphous layer 12i are formed by irradiating a laser. Thereafter, a second conductivity-type layer 22p to which a p-type dopant is added is formed on the first conductivity-type layer 12n and the intrinsic amorphous layer 12i by applying the conventional chemical vapor deposition (CVD) method such as the plasma CVD method or the like. Thereafter, as in the embodiment described above, an insulation layer 14, an n-side electrode 16n, and a p-side electrode 16p are formed.

In the embodiment described above, while the present disclosure of this patent application is described as being applied to the rear surface junction-type solar cell, the present disclosure of this patent application can be applied not only to the rear surface junction-type solar cell but also to other solar cells.

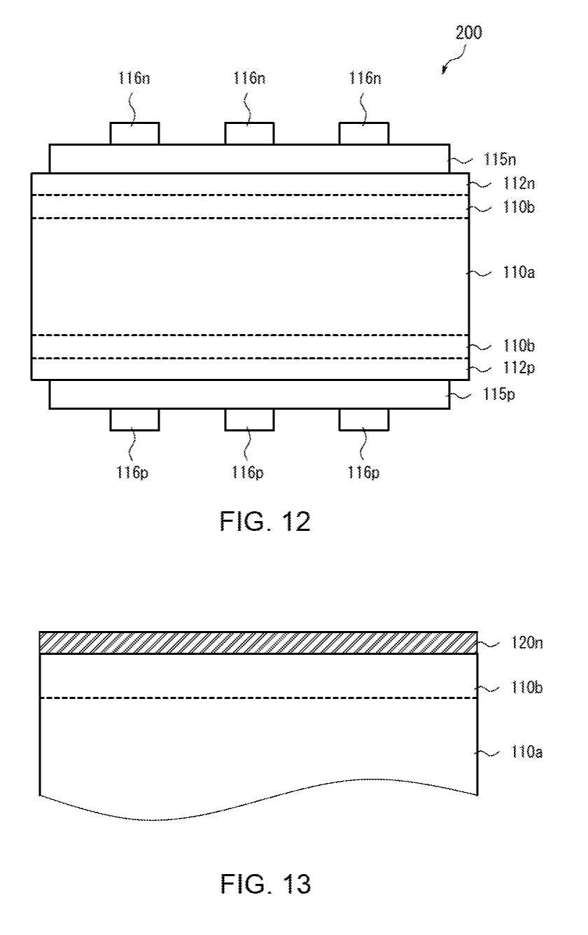

Hereinafter, referring to FIGS. 12 to 16, a solar cell 200 and a method for manufacturing the solar cell 200 according to a different embodiment will be described. FIG. 12 is a sectional view illustrating the structure of the solar cell 200 according to the different embodiment. The solar cell 200 includes a semiconductor substrate 110, a first conductivity-type layer 112n, a second conductivity-type layer 112p, a transparent conductive layer 115, and an electrode layer 116. The transparent conductive layer 115 constitutes an n-side transparent conductive layer 115n or a p-side transparent conductive layer 115p. The electrode layer 116 constitutes an n-side electrode 116n or a p-side electrode 116p. The solar cell 200 is a solar cell having the electrode layer 116 provided on each of a light receiving surface side and a rear surface side thereof.

The semiconductor substrate 110 has a first main surface A provided on the light receiving surface side and a second main surface B provided on the rear surface side. A similar silicon wafer to that of the embodiment described above can be used for the semiconductor substrate 110. In this embodiment, the semiconductor substrate 110 includes a bulk portion 110a of an n-type single crystal silicon, n⁺-type surface portions 110b, and amorphous silicon layers, which will be described later.

The amorphous silicon layers (a first conductivity-type layer 112n, a second conductivity-type layer 112p) are provided on the first main surface A and the second main surface B of the semiconductor substrate 110, respectively. In this different embodiment, the first main surface A is covered substantially entirely by the first conductivity-type layer 112n, and the second main surface B is covered substantially entirely by the second conductivity-type layer 112p. In this different embodiment, the first conductivity-type layer 112n and the second conductivity-type layer 112p may contain microcrystal silicon.

The first conductivity-type layer 112n is made up, for example, of an n-type amorphous silicon to which a dopant such as phosphorus (P), arsenic (As) or the like is added and which contains hydrogen (H). The second conductivity-type layer 112p is made up, for example, of a p-type amorphous silicon to which a dopant such as boron (B) or the like is added and which contains hydrogen (H). The first conductivity-type layer 112n and the second conductivity-type layer 112p each have a thickness, for example, of the order of several nm to 100 nm. The n-type amorphous silicon and the p-type amorphous silicon have a dopant concentration of 5×10²¹ cm⁻³ or smaller, as a typical example. An intrinsic amorphous layer, not shown, is preferably provided between the semiconductor substrate 110 and the first conductivity-type layer 112n and between the semiconductor substrate 110 and the second conductivity-type layer 112p.

The n-side transparent conductive layer 115n and the n-side electrode 116n are formed on the first conductivity-type layer 112n to collect electrons. The p-side transparent conductive layer 115p and the p-side electrode 116p are formed on the second conductivity-type layer 112p to collect positive holes. The n-side transparent conductive layer 115n and the p-side transparent conductive layer 115p preferably contain transparent conductive oxide (TCO) such as tin oxide (SnO₂), zinc oxide (ZnO), indium tin oxide (ITO) or the like. The n-side electrode 116n and the p-side electrode 116p preferably contain metal such as copper (Cu), tin (Sn), gold (Au), silver (Ag), aluminum (Al) or the like. The n-side transparent conductive layer 115n and the p-side transparent conductive layer 115p are provided in such a manner as to cover the first conductivity-type layer 112n and the second conductivity-type layer 112p, respectively, substantially entirely. The n-side electrode 116n and the p-side electrode 116p are provided in such a manner as to expose partially surfaces of the first conductivity-type layer 112n and the second conductivity-type layer 112p, respectively.

A method for forming the n-side transparent conductive layer 115n and the p-side transparent conductive layer 115p is not particularly limited, and hence, the n-side transparent conductive layer 115n and the p-side transparent conductive layer 115p can be formed using the thin film forming method such as the sputtering method, the chemical vapor deposition (CVD) method, or the like. A method for forming the n-side electrode 116n and the p-side electrode 116p is not particularly limited, and hence, the n-side electrode 116n and the p-side electrode 116p can be formed, for example, by using a printing method such as a screen print method or an ink jet method, a plating method such as electrolytic plating, or a combination thereof.

Following this, referring to FIGS. 13 to 16, a method for manufacturing the solar cell 200 of this different embodiment will be described. In the manufacturing method illustrated in FIGS. 13 to 16, a side of the solar cell 200 illustrated in FIG. 12 where the first main surface A, where the first conductivity-type layer 112n is provided, is formed will be described. However, the following description will also be true with a side of the solar cell 200 where the second main surface B, where the second conductivity-type layer 112p is provided, is formed.

As illustrated in FIG. 13, an n-type dopant diffusion layer 120n is formed on the first main surface A of the semiconductor substrate 110. As in the embodiment described above, the n-type dopant diffusion layer 120n is a resin layer containing a dopant such as phosphorus (P), arsenic (As) or the like, which are n-type dopants. The n-type dopant diffusion layer 120n is formed substantially entirely over the first main surface A of the semiconductor substrate 110.

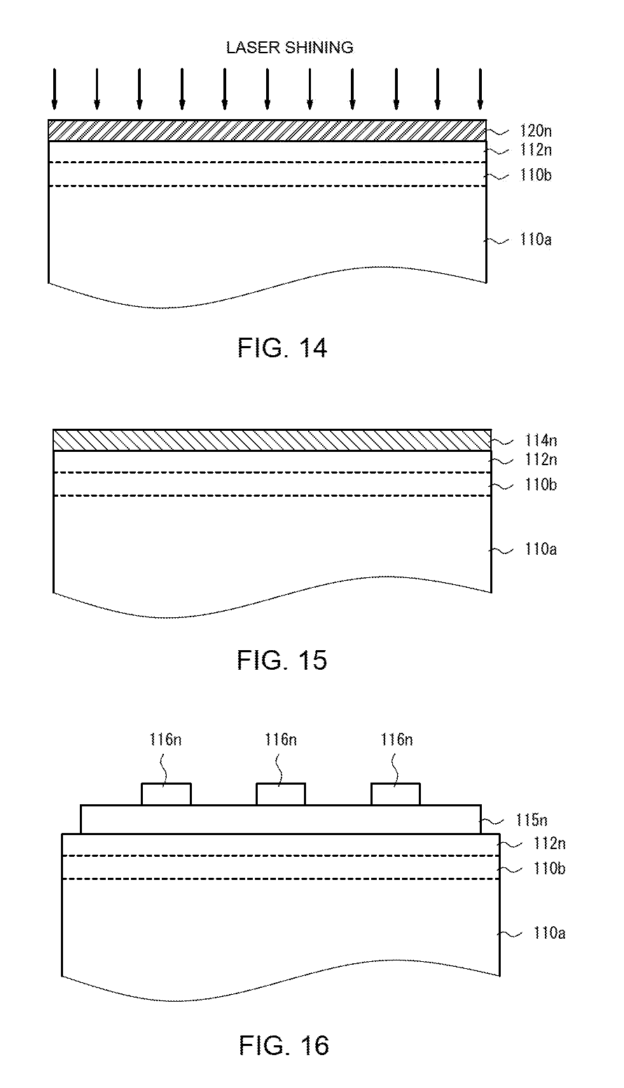

Next, as illustrated in FIG. 14, a laser is irradiated on the n-type dopant diffusion layer 120n and the semiconductor substrate 110 to thereby form a first conductivity-type layer 12n. A crystalline semiconductor on the surface of the semiconductor substrate 110 is modified into an amorphous semiconductor by irradiating the laser on a surface of the first main surface A of the semiconductor substrate 110. A similar laser to that of the embodiment described above can be used as the laser so irradiated. By performing this treatment, an area that is at a depth of several nm or greater to 100 nm or smaller from the surface of the first main surface A of the semiconductor substrate 110 is made amorphous. At the same time, the n-type dopant is diffused from the n-type dopant diffusion layer 120n, and a first conductivity-type layer 112n is formed.

As this occurs, since an interface between the semiconductor substrate 110 and the first conductivity-type layer 112n is not exposed externally, an oxygen concentration of the semiconductor substrate 110 becomes substantially equal to an oxygen concentration of the first conductivity-type layer 112n.

Next, as illustrated in FIG. 15, an insulation layer 114n is formed on the first conductivity-type layer 112n. A method for forming the insulation layer 114 is not particularly limited, and hence, the insulation layer 114n can be formed through the chemical vapor deposition (CVD) method such as the plasma CVD method employing a mixed gas of a hydrogenated silicon gas such as a silane gas and oxygen or nitrogen. By doing this, silicon oxide (SiO₂), silicon nitride (SiN), and silicon oxynitride (SiON), which all contain hydrogen, can be formed.

An annealing treatment is preferably performed after or during formation of the insulation layer 114n. By doing this, hydrogen is introduced from the insulation layer 114n into the first conductivity-type layer 112n due to heat generated by the annealing treatment, whereby defects in the first conductivity-type layer 112n are inactivated (passivation).

Thereafter, as illustrated in FIG. 16, the insulation layer 114n formed on the first conductivity-type layer 112n is removed. Then, an n-side transparent conductive layer 115n and an n-side electrode 116n are formed on the first conductivity-type layer 112n. The n-side transparent conductive layer 115n can be formed by applying the thin film forming method, and the n-side electrode 116n can be formed by applying the printing method, the plating method, or the like.

The solar cell 200 of this embodiment can be formed by the manufacturing method that has been described heretofore. Thus, as in the embodiment described above, a good junction interface between the crystalline semiconductor and the amorphous silicon layer of the semiconductor substrate 110 can be formed.

Thus, while the present disclosure has been described by reference to the embodiments and the modified examples, the present disclosure is not limited to the embodiments, and what results from combining or replacing the configurations of the embodiments as required is also included in the present disclosure.

### REFERENCE SIGNS LIST

10, 110 semiconductor substrate; 10a, 110a bulk portion; 10b, 110b surface portion; 12i intrinsic amorphous layer; 12n, 112n first conductivity-type layer; 12p, 112p second conductivity-type layer; 14, 114n, 114p insulation layer; 16, 116 electrode layer; 16n, 116n n-side electrode; 16p, 116p p-side electrode; 20n, 120n n-type dopant diffusion layer; 20p, 120p p-type dopant diffusion layer; 22p second conductivity-type layer; 100, 102, 200 solar cell.

1. A method for manufacturing a solar cell, comprising:
a first step of forming an amorphous silicon layer by irradiating a laser on a crystalline silicon substrate to make a surface of the crystalline silicon substrate amorphous; and
a second step of introducing hydrogen into the amorphous silicon layer.

2. The method for manufacturing a solar cell of claim 1, further comprising:
a third step of forming an electrode layer on the amorphous silicon layer.

3. The method for manufacturing a solar cell of claim 2,
wherein the first step comprises:
a step of forming a dopant diffusion layer containing an n-type or a p-type dopant on the surface of the crystalline silicon substrate; and
a step of irradiating a laser on the dopant diffusion layer and the crystalline silicon substrate.

4. The method for manufacturing a solar cell of claim 2,
wherein the solar cell is a rear surface junction-type solar cell in which the electrode layer is not provided on a light receiving surface side and is provided on a rear surface opposite to the light receiving rear surface side, and
wherein the first step comprises:
a step of forming a texture structure on the light receiving surface side of the crystalline silicon substrate; and
a step of forming the crystalline amorphous silicon layers of an n type and a p type on the rear surface of the crystalline silicon substrate.

5. The method for manufacturing a solar cell of claim 1,
wherein the second step comprises:
a step of forming an insulation layer containing any one of silicon oxide, silicon nitride and silicon oxynitride, the silicon oxide, silicon nitride and silicon oxynitride containing hydrogen, on the amorphous silicon layer; and
a step of performing an annealing treatment after or during formation of the insulation layer.

6. A solar cell, comprising:
a crystalline silicon substrate; and
an electrode layer formed on the crystalline silicon substrate,
wherein the crystalline silicon substrate comprises:
a crystalline silicon layer; and
an amorphous silicon layer, and
wherein a difference between an oxygen concentration of the crystalline silicon layer and an oxygen concentration of the amorphous silicon layer is no more than a 10-fold difference.

7. The solar cell of claim 6,
wherein a texture structure is formed on a light receiving surface side of the crystalline silicon substrate,
wherein the amorphous silicon layer is provided on a rear surface side of the crystalline substrate where no texture structure is formed,
wherein the amorphous silicon layer comprises:
a first conductivity-type layer containing an n-type dopant; and
a second conductivity-type layer containing a p-type dopant, and
wherein the electrode layer is provided on the first conductivity-type layer and the second conductivity-type layer and is not provided on the light receiving surface side of the crystalline silicon substrate.

8. The solar cell of claim 7,
wherein the electrode layer comprises:
an n-side electrode formed on the first conductivity-type layer; and
a p-side electrode formed on the second conductivity-type layer, and further comprises:
an insulation layer formed on the amorphous silicon layer and between the n-side electrode and the p-side electrode.
